(19) United States
(12) Patent Application Publication
(10) Pub. No.: US 2015/0357206 A1
(43) Pub. Date: Dec. 10, 2015

(54) USE OF AN ETCH STOP IN THE MIM CAPACITOR DIELECTRIC OF A MMIC

(71) Applicant: Raytheon Company, Waltham, MA (US)

(72) Inventor: James W. McClymonds, Waltham, MA (US)

(73) Assignee: Raytheon Company, Waltham, MA (US)

(21) Appl. No.: 14/297,875

(22) Filed: Jun. 6, 2014

(51) Int. Cl. H01L 21/3213; H01L 27/06; H01L 49/02

(52) U.S. Cl. CPC H01L 21/32139; H01L 28/40; H01L 27/0629

(57) ABSTRACT

A structure having; a body; a pair of capacitors disposed over different portions of a surface of the body; a first one of the capacitors having an upper conductor and a lower conductor separated a dielectric layer; and a second one of the pair of capacitors having an upper conductor and a lower conductor separated a dielectric structure, the dielectric structure having a lower dielectric layer, and an upper dielectric layer, wherein the material of the lower dielectric layer is different from the material of the upper dielectric layer.

### TECHNICAL FIELD

This disclosure relates generally to MMICs having capacitors with different capacitances.

### BACKGROUND

As is known in the art, it is sometimes desirable to provide a plurality of different capacitors having different capacitances on a common surface of a substrate providing a Monolithic Microwave Integrated Circuit (MMIC).

### SUMMARY

In accordance with the disclosure, a structure is provided, comprising: a body; a pair of capacitors disposed over different portions of a surface of the body; a first one of the capacitors having an upper conductor and a lower conductor separated by a dielectric layer; and a second one of the pair of capacitors having an upper conductor and a lower conductor separated a dielectric structure, the dielectric structure having a lower dielectric layer, and an upper dielectric layer, wherein the material. of the lower dielectric layer being different from the material of the upper dielectric layer.

The use of different dielectric materials within the metal-insulator-metal (MIM) capacitor dielectric of a MMIC results in lower MMIC cost, higher reliability and higher performance.

In one embodiment, a method is provided for forming a plurality of metal-insulator-metal (MIM) capacitors on a surface of a body, the capacitors having different insulator dielectric thicknesses. The method includes: forming a plurality of lower metal conductors over the surface of the body, each one of the conductors providing a lower electrode for a corresponding one of the capacitors; depositing a first dielectric layer over the surface of the body, portions of the first dielectric layer being disposed over the plurality of lower conductors; depositing a second dielectric layer over the first dielectric layer including the portions of the first dielectric disposed over the plurality of lower conductors; forming a mask over the second dielectric layer, such mask having a window therein exposing a first portion of the second dielectric layer disposed over a first one of the lower metal conductors while covering a second portion of the second dielectric layer over a second one of the lower metal conductors; exposing the mask to an etch, the etch having a etch rate in the second dielectric layer being greater than the etch rate in the first dielectric layer, the etch removing the second dielectric layer exposed by the window exposing an underlying portion of the first dielectric layer while leaving the underlying portion of the first dielectric layer over the first one of the lower metal conductors; removing the mask exposing both the second dielectric layer over a second one of the lower metal conductors and the underlying portion of the first dielectric layer over the first one of the lower metal conductors; depositing an upper metal layer over the exposed second portion of the second dielectric layer over a second one of the lower metal conductors and the underlying portion of the first dielectric layer over the first one of the lower metal conductors; and patterning the upper metal layer to form an upper electrode for a first one of the capacitors over the first one of the lower electrodes and an upper electrode for a second one of the capacitors.

With such an arrangement, a capacitor dielectric stack-up is provided with an etch stop layer (the first dielectric layer) allows design flexibility to remove or not remove the top dielectric layer and change the total thickness.

The layer thicknesses of the dielectric layers can be Chosen so that a capacitor having both layers can withstand the highest DC plus voltage within the MMIC thereby eliminating the need for multiple capacitors in series. If the upper dielectric layer is etched away to leave only the lower dielectric layer, the lower dielectric layer thickness can be chosen so that it has an adequate breakdown rating for DC bypassing with a smaller area.

The method can be used to eliminate air bridges: When it is required to have a signal cross another conductor on a without being connected, rather than using an air bridge; the upper metal therein when used with high power may sometimes degrade due to the temperature rise caused by the high RF or DC current levels. By eliminating the air bridge as a cross-over in accordance with the disclosure, a cross-over in accordance with the disclosure has a much better heat path than an air bridge so it will be much less prone to failure while still being able to withstand high RF or DC voltage levels without breakdown.

In one embodiment, the method includes; forming an additional lower conductor over the surface of the body. Portions of the first dielectric layer are also deposited over the additional lower conductor; portions of the second dielectric layer are deposited over the portions of the first dielectric layer over the additional lower conductor; portions of the mask are deposited over a portion of the second insulating layer over the additional lower metal conductors; portions of the upper metal layer are disposed over the second dielectric layer above the additional lower metal conductor. The patterning of the upper metal layer forms a conductor crossing over the additional lower conductor.

In one embodiment, the thick top dielectric layer over a Field Effect Transistor (FM) region is etched away to eliminate its additional dielectric loading on the FET performance. Therefore the above benefits for capacitors and air bridge elimination can be achieved with little or no performance impact to the PETs. The added flexibility to choose the thicknesses of the two dielectric layers could also be used to even improve the FET performance.

The details of one or more embodiments of the disclosure are set forth. in the accompanying drawings and the description below. Other features, objects, and advantages of the disclosure will be apparent from the description and drawings, and from the claims.

### DESCRIPTION OF DRAWINGS

FIG. 1 is a simplified diagraminatical sketch of an Monolithic Microwave Integrated Circuit (MMIC) according to the disclosure; and

FIGS. 2A-2K are simplified diagrammatical sketch of a process used to form the MMIC at various steps in the manufacture thereof according to the disclosure.

Like reference symbols in the various drawings indicate like elements.

### DETAILED DESCRIPTION

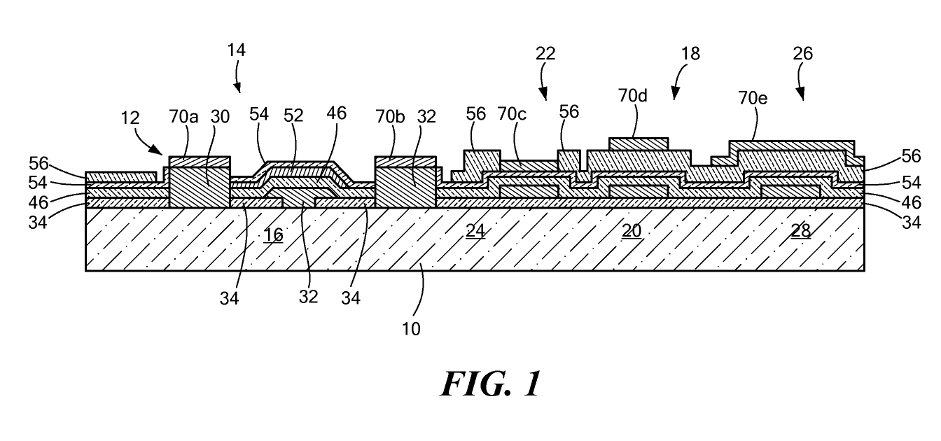

Referring now to FIG. 1, a body 10, here for example a semiconductor body, here, for example, GaN, is formed into a Monolithic Microwave Integrated Circuit (MMIC) 12. Here, for simplicity, the MMIC circuit 12 will be formed having a FET 14 in a PET region 16 of the body 10, a high voltage capacitor 18, in a high voltage capacitor region 20 of the body 10, slow voltage capacitor 22 formed in a low voltage region 24 of the body 10, and a conductive cross over 26 formed in a cross over region 28 of the body 10, as indicated.

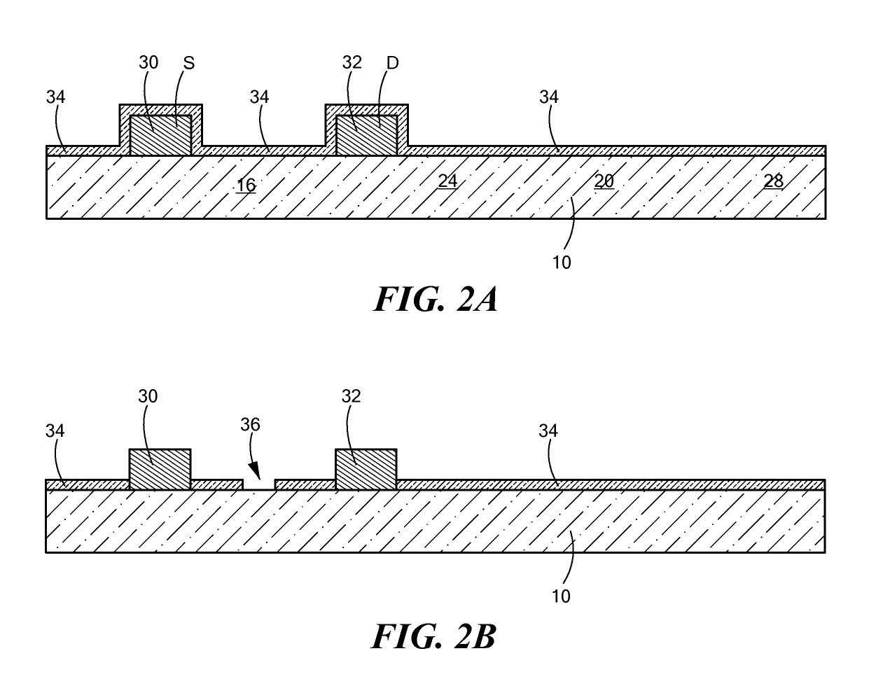

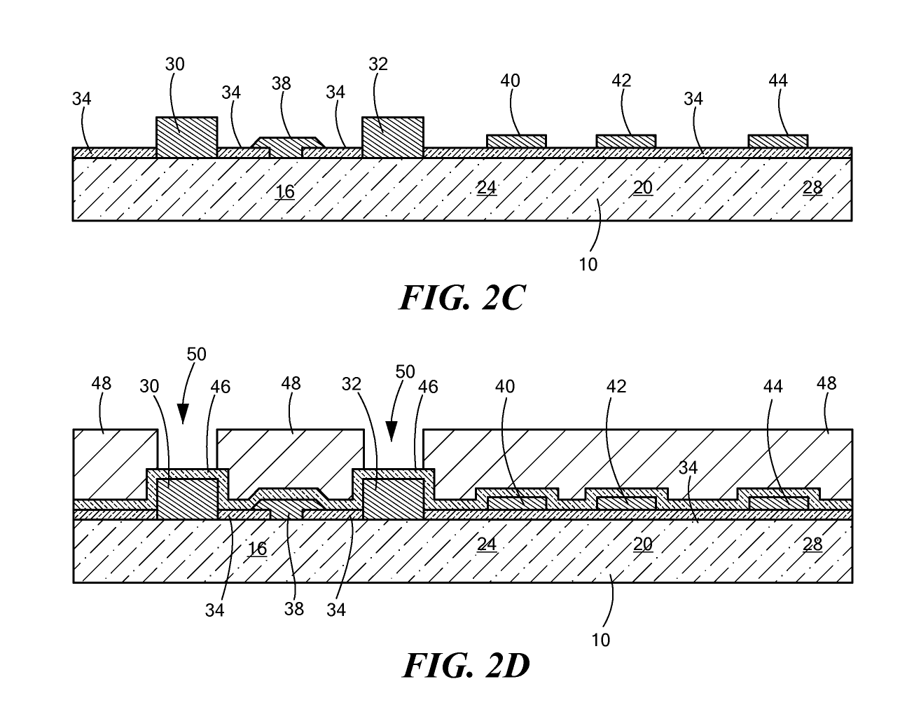

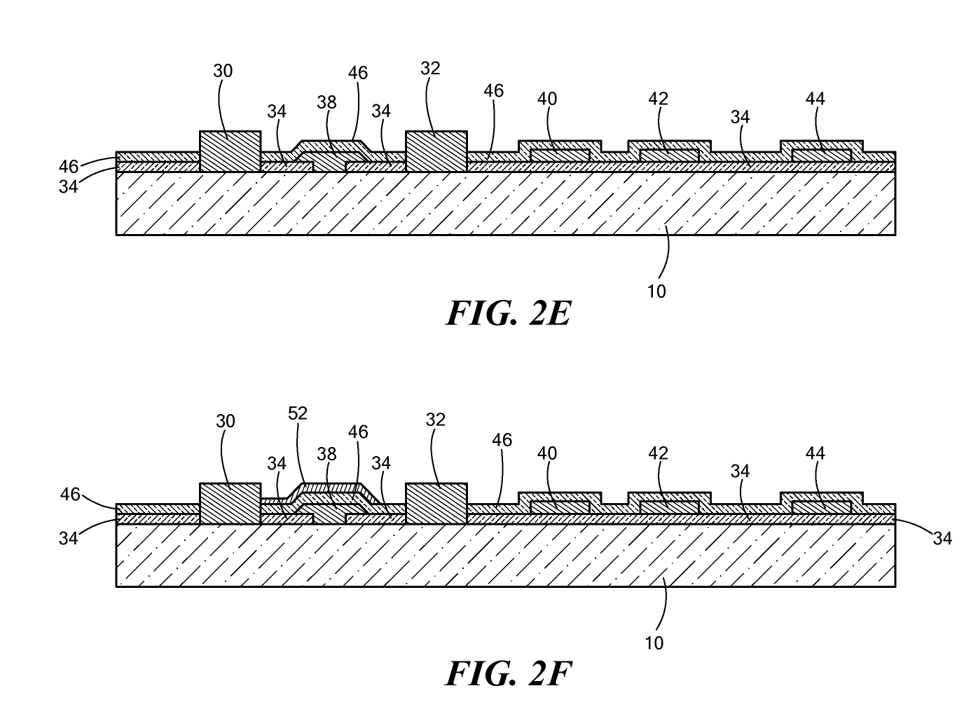

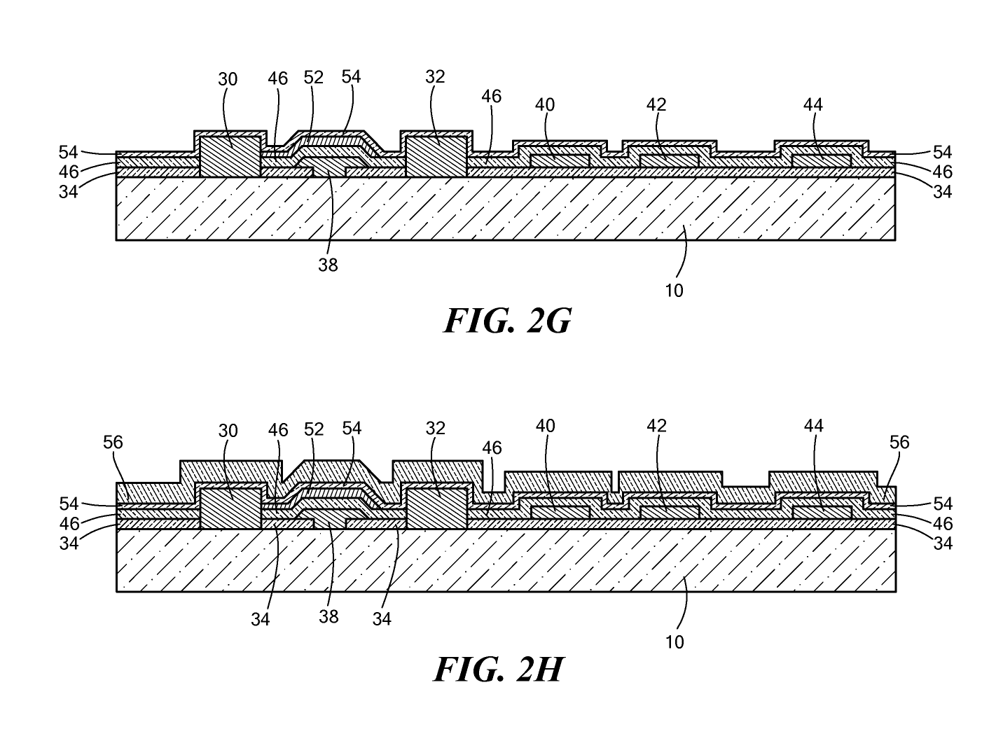

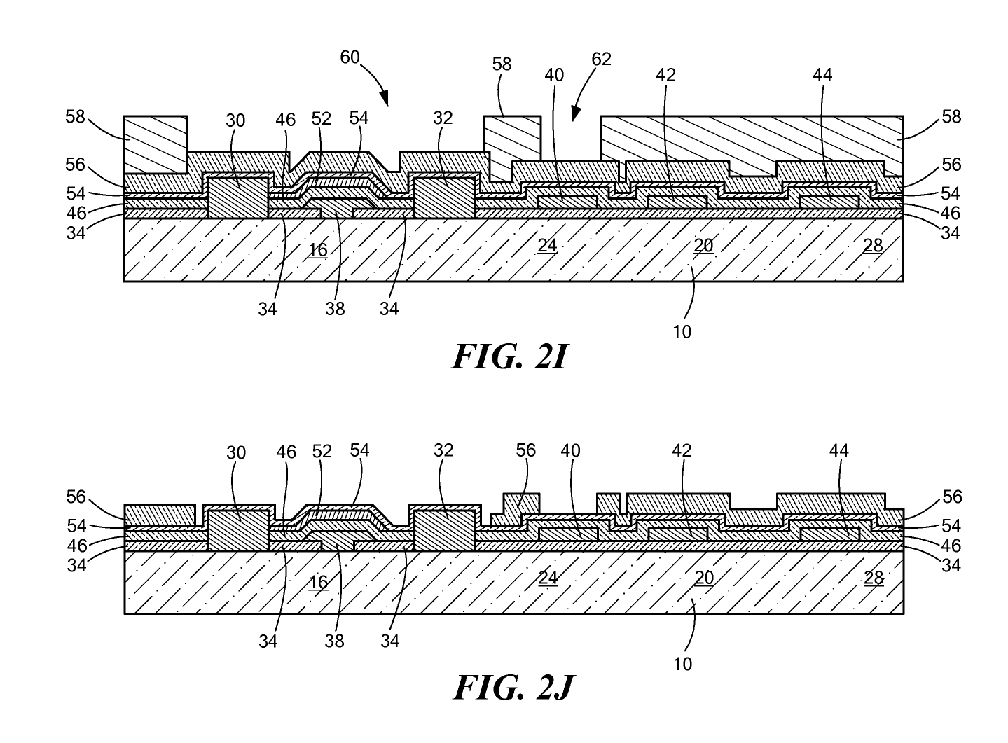

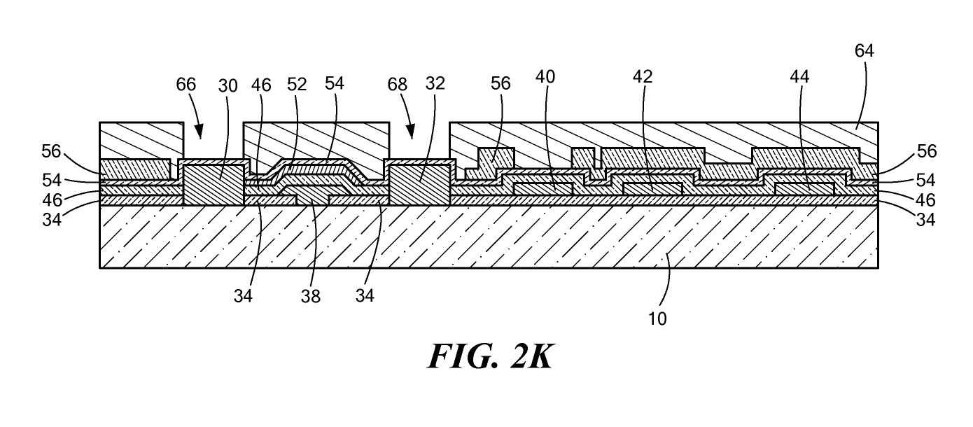

More particularly, referring now to FIGS. 2A-2K, source, and drain electrodes 30, 32 are formed in ohmic contact with the body 10, as shown, using any conventional process. A dielectric layer 34, here for example a 500 Angstrom thick layer of Silicon Nitride (SiN) is deposited over the upper surface of the body 10 and over the source and drain electrodes 30, 32. A window 36 (FIG. 2B) is formed in the dielectric layer 34 to expose the gate region of the FET. A gate electrode 38 (FIG. 2C) is formed in Schottky contact with the exposed portion of the body 10, as shown.

Next, lower conductors 40, 42 and 44 are formed on the first dielectric layer 34 over the high voltage capacitor region 20, the low voltage capacitor region 24, and the cross-over region 28 using conventional photolithographic processing, for example. Next, a second. dielectric layer 46 (FIG. 2D), here for example a 2000 Angstrom thick layer of Si₃N₄ is deposited over the surface of the structure; it being noted that the second dielectric layer 46 is deposited on the source electrode 30, the gate electrode 38, the drain electrode 32, and the lower conductors 40, 42, 44 with portions second dielectric layer 46 being deposited on portions of the first dielectric layer 34, as shown.

Next, a mask 48 is formed on the surface of the MMIC, the mask having windows 50 over the source and drain contacts 30, 32, as shown. The portions of the second dielectric layer 46 exposed by the windows 50 are etched away using conventional lithographic etching techniques, for example, to expose the source 30 and drain 32.

Next, the mask 48 is removed leaving the structure shown in FIG. 2E.

Next, a field plate 52 (FIG. 2F) is formed, as shown, using any conventional deposition, photolithographic, etching process.

Next, a dielectric etch stop layer 54 (FIG. 2G), here for example Al₂O₃ having, for example, a thickness of 50 Angstroms, is deposited over the structure. Next, a fourth dielectric layer 56, here for example, a 6000 Angstroms thick layer of Si₃N₄ resulting in the structure shown in FIG. 2H.

Next, a mask. 58 is formed on the surface of the structure, the mask 58 having windows 60, 62 exposing the FBI region 16 and the low voltage capacitor region 24 but remaining over the high voltage capacitor region 20 and the cross over region 28, as shown in FIG. 21. Next, the mask 58 is exposed to an etchant, here for example SF₆ (sulfur hexafluoride) using a Reactive Ion Etcher to remove portions of the fourth dielectric layer 56 exposed by the windows 60, 62, thereby exposing underlying portions of the etch stop layer 54 producing the structure shown in FIG. 2J after the mask 58 is removed. It is noted that the SF₆ etches away the exposed portions of the Si₃N₄ layer at a substantially higher rate (for example at least two orders of magnitude faster) and therefore in essence stops at the underlying portions of the Al₂O₃ etch stop layer 54.

Next, a new mask 64 (FIG. 2K) is formed over the structure with windows 66, 68 in the mask 64 exposing portions of the etch stop layer 54 disposed over the source and drain electrodes 30, 32. The exposed portions of the etch stop layer 54 are etched away using a dry etch of Cl₂ and BCl₃

Next, the mask 64 is removed. A conductor is deposited over the surface of the structure and patterned into the upper conductors 70a for the source electrode, the drain electrode 70b, the high voltage capacitor 70d, the low voltage capacitor 70c and the cross over conductor 700 using conventional photolithographic-etching techniques, for example, producing the MMIC 12 shown in FIG. 1.

A number of embodiments of the disclosure have been described. Nevertheless, it will be understood that various modifications may be made without departing from the spirit and scope of the disclosure. For example, a two dielectric structure may be formed, by eliminating etch stop layer 54 and making the lower dielectric layer 46 from the same dielectric material that had been used for the etch stop layer 54. The thickness of the lower dielectric layer 46 is chosen to meet the capacitance and breakdown voltage requirements for capacitor 22 (FIG. 1.), For example, the lower dielectric layer 46 may be, a 2000 Angstrom thick layer of Al₂O₃ and the upper layer 56 may be a 6000 Angstrom thick layer of Si₃N₄; Where the etch rate to a given etch is substantially faster (for example, at least two orders of magnitude faster) to the Si₃N₄ that to the Al₂O₃ Thus, such a two-dielectric structure may be used in place of a three-dielectric structure having a lower 2000 Angstrom thick Si₃N₄ layer, a 50 Angstrom thick Al₂O₃ middle, etch stop layer , and a 6000 Angstrom thick Si₃N₄ upper dielectric layer. Accordingly, other embodiments are within the scope of the following claims.

What is claimed is:

1. A method for forming a plurality of metal-insulator-metal (MIM) capacitors on a surface of a body, the capacitors having different insulator thicknesses, comprising:
forming a plurality of lower metal conductors over the surface of the body, each one of the conductors providing a lower electrode for a corresponding one of the capacitors;
depositing a first insulator layer over the surface of the body, portions of the first insulator layer being disposed over the plurality of lower conductors;
depositing a second insulator layer over the first insulator layer;
forming a mask over the second insulating layer, such mask having a window therein exposing a first portion of the second insulating layer disposed over a first one of the lower metal conductors while covering a second portion of the second insulating layer over a second one of the lower metal conductors;
exposing the mask to an etch, the etch having a etch rate in the second insulating layer being greater than the etch rate in the first insulator layer, the etch removing the first portion of the second insulating layer exposed by the window exposing an underlying portion of the first insulator layer while leaving the underlying portion of the second insulating layer over the second one of the lower metal conductors;
removing the mask exposing both the second portion of the second insulating layer over a second one of the lower metal conductors and the underlying portion of the first dielectric layer over the first one of the lower metal conductors;
depositing a metal layer over the exposed second portion of the second insulating layer over a second one of the lower metal conductors and the underlying portion of the first dielectric over the first one of the lower metal conductors;
patterning the metal layer to form an upper electrode for a first one of the capacitors over the first one of the lower electrodes and an upper electrode for a second one of the capacitors.

2. The method recited in claim 1 including:
forming an additional lower conductor over the surface of the body laterally spaced from the plurality of capacitors;
wherein:
portions of the first insulator layer are also deposited over the additional lower conductor;
portions of the second insulator layer are deposited over the portions of the first insulator layer over the additional lower conductors;
non-windowed portions of the mask are deposited over a portion of the second insulating layer over the additional lower metal;
portions of the metal layer are disposed over the second insulator layer in the region above the additional lower metal conductor;
the patterning of the metal layer forms a cross-over conductor over the additional lower conductor.

3. The method recited in claim 1 including an additional insulator layer disposed under the first insulator layer.

4. The method recited in claim 1 including forming a Field Effect Transistor on a portion of the surface of the body laterally spaced from the pair of capacitors wherein the second insulator layer has a portion also deposited over a Field Effect Transistor; and
Wherein the mask has a second window exposing the portion of the second insulator layer deposited over the Field Effect Transistor and wherein the etch removes portions of the second insulating layer exposed by the window.

5. A structure, comprising:
a body;
a pair of capacitors disposed over different portions of a surface of the body;
a first one of the capacitors having an upper conductor and a lower conductor separated a dielectric layer; and
a second one of the pair of capacitors having an upper conductor and a lower conductor separated by a dielectric structure, the dielectric structure having a lower dielectric layer, and an upper dielectric, layer, wherein the material of the upper dielectric layer is different from the material of the lower dielectric layer.

6. The structure recited in claim 5 wherein the upper dielectric layer is thicker than the lower dielectric layer.
